(19) United States
(12) Patent Application Publication
(10) Pub. No.: US 2026/0005099 A1
(43) Pub. Date: Jan. 1, 2026

(54) ELECTRONIC PACKAGE

(71) Applicant: SILICONWARE PRECISION INDUSTRIES CO., LTD., Taichung City (TW)

(72) Inventor: Chuan-Shun LI, Taichung City (TW)

(21) Appl. No.: 19/176,718

(22) Filed: Apr. 11, 2025

(30) Foreign Application Priority Data
Jul. 1, 2024 (TW) 113124542

(51) Int. Cl. H01L 23/373; H01L 23/00; H01L 23/367

(52) U.S. Cl. CPC H01L 23/3737; H01L 23/3735; H01L 24/29; H01L 23/3675; H01L 24/32; H01L 2224/29082; H01L 2224/29109; H01L 2224/2929; H01L 2224/32225

(57) ABSTRACT

An electronic package is provided and includes a carrier structure, an electronic component disposed on the carrier structure, a heat dissipation structure disposed on the electronic component via a thermal interface material, a back side metallization formed on the electronic component and connected to the thermal interface material, and a conductive adhesive provided between the thermal interface material and the back side metallization. The surface adhesiveness of the conductive adhesive is used to limit the displacement of the thermal interface material relative to the back side metallization, thereby preventing the displacement of the thermal interface material from causing poor bonding between the heat dissipation structure and the electronic component, which would affect the heat dissipation efficiency of the electronic package.

### CROSS-REFERENCE TO RELATED APPLICATIONS

The present application is based upon and claims the right of priority to TW patent application No. 113124542, filed on Jul. 1, 2024, the disclosure of which is hereby incorporated by reference herein in its entirety for all purposes.

### BACKGROUND

### 1. Technical Field

The present disclosure relates to an electronic package, and more particularly, to an electronic package that has a heat dissipation structure.

### 2. Description of Related Art

With the rise and booming development of various applications and technologies that require high-speed computing, such as e-sports gaming, high-resolution audio and video multimedia, and autonomous driving, as well as the demand for miniaturization of related equipment, the number of components contained in the semiconductor chip (i.e., integrated circuit [IC]) adopting the package structure, such as flip-chip ball grid array (FCBGA) is not only increasing, but the processing and computing speeds are also becoming faster and faster, so that the heat generated is more and more considerable, and the requirements for heat dissipation structures are also higher and higher.

FIG. 1 is a schematic cross-sectional view showing a conventional semiconductor package 1. The semiconductor package 1 includes a packaging substrate 11, a semiconductor chip 12 mounted on an upper side of the packaging substrate 11 in a flip-chip manner, and a heat dissipation sheet 13.

The heat dissipation sheet 13 is made of copper, and the semiconductor chip 12 is made of silicon. In order to improve the bonding effect between the heat dissipation sheet 13 and the semiconductor chip 12 as well as the heat dissipation effect, the industry often applies a back side metallization (BSM) 15 and a thermal interface material (TIM) 14 on a back side of the semiconductor chip 12. Considering that the indium metal sheet has a thermal conductivity of up to 86 W/mK and its softness can withstand the thermal stress generated during the operation of the product, the semiconductor industry often uses the indium metal sheet as the thermal interface material 14.

In addition, with the requirement for thin and light products increases, the thickness and weight of the indium metal sheet continue to decrease, creating new challenges for packaging technology. For example, in order to prevent the light and thin indium metal sheet from not being perfectly aligned with the position of the semiconductor chip 12 during the packaging operation, or even being blown away from the product surface by the air flow of the pipe of production line, an adhesive layer 16 is applied between the TIM 14 and the BSM 15 to fix the TIM 14 to the semiconductor chip 12.

However, the semiconductor package wraps during the thermal cycling reliability test, so no matter how much the adhesive is controlled, it would be squeezed into the inner edge of the indium metal sheet, resulting in incomplete evaporation. Furthermore, the adhesive is made of polymer material, and would form an obstacle when the indium metal sheet is bonded to the BSM, resulting not only in incomplete bonding but also in loss of heat dissipation performance.

Therefore, how to overcome the above-mentioned problems of the prior art has become an urgent issue for the industry to solve.

### SUMMARY

In view of the various deficiencies of the prior art, the present disclosure provides an electronic package, which comprises: a carrier structure; an electronic component disposed on the carrier structure; a heat dissipation structure disposed on the electronic component; a thermal interface material provided between the electronic component and the heat dissipation structure, wherein the heat dissipation structure is attached to the electronic component via the thermal interface material; a back side metallization formed on the electronic component and connected to the thermal interface material; and a conductive adhesive provided between the thermal interface material and the back side metallization and including metal fillers.

In the aforementioned electronic package, the electronic component has an active surface and an inactive surface opposite to the active surface, and the active surface of the electronic component is electrically connected to the carrier structure via a plurality of conductive bumps in a flip-chip manner.

In the aforementioned electronic package, the heat dissipation structure has a top sheet and a supporting leg, an end of the supporting leg is bonded to the top sheet, another end of the supporting leg is disposed on the carrier structure, and a bottom surface of the top sheet is opposite to a top surface of the electronic component.

In the aforementioned electronic package, the thermal interface material is a liquid metal, a metal layer, or a glue with thermal conductivity properties.

In the aforementioned electronic package, the thermal interface material is an indium layer.

In the aforementioned electronic package, the back side metallization includes at least one of an aluminum layer, a titanium layer, a chromium layer, a nickel layer, a nickel-vanadium alloy layer, and a copper layer.

In the aforementioned electronic package, a distribution area of the conductive adhesive is at most 1% of a distribution area of the back side metallization.

In the aforementioned electronic package, the metal fillers have a first thermal conductivity, the thermal interface material has a second thermal conductivity, and the first thermal conductivity is less than the second thermal conductivity.

In the aforementioned electronic package, the conductive adhesive is used as a fixing material between the thermal interface material and the back side metallization.

In the aforementioned electronic package, the conductive adhesive has adhesiveness for limiting a displacement of the thermal interface material relative to the back side metallization.

In the aforementioned electronic package, the conductive adhesive is made of a composite material composed of a polymer adhesive and the metal fillers.

By the implementation of the present disclosure, the conductive adhesive is mainly provided between the thermal interface material and the back side metallization, because the conductive adhesive has adhesiveness to limit the displacement of the thermal interface material relative to the back side metallization, thereby preventing the displacement of the thermal interface material from causing poor bonding between the heat dissipation structure and the electronic component in the subsequent process, which would affect the heat dissipation efficiency of the electronic package. In addition, the conductive adhesive is made of a composite material composed of polymer adhesive and metal fillers, which can not only achieve the effect of molding and adhesion, but also the metal fillers can complement the thermal impedance of the polymer adhesive, allowing the heat from the heat source to be transferred outward through the dense and tiny metal fillers.

### BRIEF DESCRIPTION OF THE DRAWINGS

FIG. 1 is a schematic cross-sectional view of a conventional semiconductor package.

FIG. 2 is a schematic cross-sectional view illustrating an electronic package according to the present disclosure.

FIG. 3 is a schematic partial enlarged view of FIG. 2.

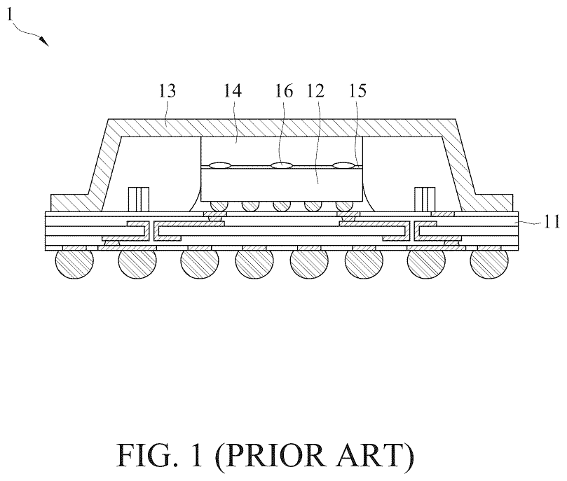

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one,” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

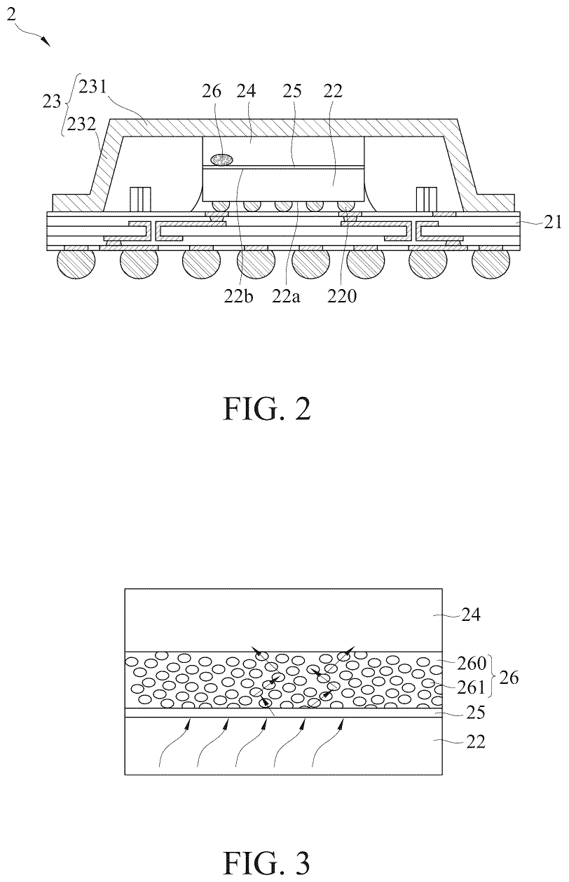

FIG. 2 is a schematic cross-sectional view illustrating an electronic package 2 according to the present disclosure. In an embodiment, the electronic package 2 comprises: a carrier structure 21; an electronic component 22 disposed on and electrically connected to the carrier structure 21; a heat dissipation structure 23 disposed on the electronic component 22; a thermal interface material (TIM) 24 provided between the electronic component 22 and the heat dissipation structure 23, wherein the heat dissipation structure 23 is attached to the electronic component 22 via the TIM 24; a back side metallization (BSM) 25 formed on the electronic component 22 and connected to the TIM 24; and a conductive adhesive 26 provided between the TIM 24 and the back side metallization 25. As shown in FIG. 3, the conductive adhesive 26 has metal fillers 261.

The carrier structure 21 is, for example, a packaging substrate with a core layer and a circuit structure, or a coreless circuit structure. The carrier structure 21 has at least one dielectric layer (made of dielectric material) and at least one circuit layer formed on the dielectric layer, such as a redistribution layer (RDL). Alternatively, the carrier structure 21 can be a lead frame, a silicon interposer, a wafer, or other board with metal routings, etc., and is not limited to the above.

The electronic component 22 is attached to the carrier structure 21 and is electrically connected to the circuit layer. The electronic component 22 is an active component, a passive component, a package structure, or a combination of the active component, the passive component and the package structure. The active component is, for example, a semiconductor chip for an application processor used in a mobile device such as a cell phone or for other computing functions, and the passive component is, for example, a resistor, a capacitor, or an inductor. In an embodiment, the electronic component 22 is a semiconductor chip and has an active surface 22a and an inactive surface 22b opposite to the active surface 22a, wherein the active surface 22a of the electronic component 22 is electrically connected to the carrier structure 21 via a plurality of conductive bumps 220 in a flip-chip manner.

The heat dissipation structure 23 is, for example, a heat dissipation sheet, a heat dissipation lid, or other component or structure having the same function. In an embodiment, the heat dissipation structure 23 has a top sheet 231 and at least one supporting leg 232, wherein one end of the supporting leg 232 is bonded to the top sheet 231, and the other end of the supporting leg 232 is disposed on the carrier structure 21, such that the bottom surface of the top sheet 231 is opposite to the top surface of the electronic component 22. The heat dissipation structure 23 is made of copper.

A thermal interface material 24 is further provided between the top surface of the electronic component 22 and the bottom surface of the top sheet 231 of the heat dissipation structure 23, so that the heat generated by the electronic component 22 is more efficiently conducted to the heat dissipation structure 23 and then dissipated to the environment. The thermal interface material 24 is, for example, a liquid metal, a metal layer, or a glue with thermal conductivity properties, and the thermal interface material 24 can be liquefied when heated and pressurized. In an embodiment, the thermal interface material 24 is, for example, an indium metal layer.

The back side metallization 25 is formed on the electronic component 22 and is connected to the thermal interface material 24. The back side metallization 25 may be a multilayer metal layer structure, for example, including at least one of an aluminum layer, a titanium layer, a chromium layer, a nickel layer, a nickel-vanadium alloy layer, and a copper layer.

Referring also to FIG. 3, the conductive adhesive 26 is provided between the thermal interface material 24 and the back side metallization 25. The conductive adhesive 26 is used as a fixing material between the thermal interface material 24 and the back side metallization 25. The conductive adhesive 26 has adhesiveness to limit displacement of the thermal interface material 24 relative to the back side metallization 25. In an embodiment, the conductive adhesive 26 is made of a composite material composed of a polymer adhesive 260 (e.g., silicone) and metal fillers (e.g., metal particles) 261, which not only achieves the effect of molding and adhesion, but also the metal fillers 261 can complement the thermal impedance of the polymer adhesive 260, allowing the heat from the heat source to be transferred through dense and tiny metal fillers 261.

In an embodiment, the metal fillers 261 are at least 88.5% to 89% by weight of the conductive adhesive 26.

In an embodiment, the metal fillers 261 have a first thermal conductivity, and the thermal interface material 24 has a second thermal conductivity. For example, the first thermal conductivity is less than the second thermal conductivity.

In an embodiment, the distribution area/region of the conductive adhesive 26 is at most 1% (preferably 0.5%) of the distribution area of the back side metallization 25.

In conclusion, the electronic package of the present disclosure is configured to provide the conductive adhesive between the thermal interface material and the back side metallization, because the conductive adhesive has adhesiveness to limit the displacement of the thermal interface material relative to the back side metallization, thereby preventing the displacement of the thermal interface material from causing poor bonding between the heat dissipation structure and the electronic component in the subsequent process, which would affect the heat dissipation efficiency of the electronic package. In addition, the conductive adhesive is made of a composite material composed of polymer adhesive and metal fillers, which can not only achieve the effect of molding and adhesion, but also the metal fillers can complement the thermal impedance of the polymer adhesive, allowing the heat from the heat source to be transferred outward through the dense and tiny metal fillers.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure;
an electronic component disposed on the carrier structure;
a heat dissipation structure disposed on the electronic component;
a thermal interface material provided between the electronic component and the heat dissipation structure, wherein the heat dissipation structure is attached to the electronic component via the thermal interface material;
a back side metallization formed on the electronic component and connected to the thermal interface material; and
a conductive adhesive provided between the thermal interface material and the back side metallization and including metal fillers.

2. The electronic package of claim 1, wherein the electronic component has an active surface and an inactive surface opposite to the active surface, and the active surface of the electronic component is electrically connected to the carrier structure via a plurality of conductive bumps in a flip-chip manner.

3. The electronic package of claim 1, wherein the heat dissipation structure has a top sheet and a supporting leg, an end of the supporting leg is bonded to the top sheet, another end of the supporting leg is disposed on the carrier structure, and a bottom surface of the top sheet is opposite to a top surface of the electronic component.

4. The electronic package of claim 1, wherein the thermal interface material is a liquid metal, a metal layer, or a glue with thermal conductivity properties.

5. The electronic package of claim 1, wherein the thermal interface material is an indium layer.

6. The electronic package of claim 1, wherein the back side metallization includes at least one of an aluminum layer, a titanium layer, a chromium layer, a nickel layer, a nickel-vanadium alloy layer, and a copper layer.

7. The electronic package of claim 1, wherein a distribution area of the conductive adhesive is at most 1% of a distribution area of the back side metallization.

8. The electronic package of claim 1, wherein the metal fillers have a first thermal conductivity, the thermal interface material has a second thermal conductivity, and the first thermal conductivity is less than the second thermal conductivity.

9. The electronic package of claim 1, wherein the conductive adhesive is used as a fixing material between the thermal interface material and the back side metallization.

10. The electronic package of claim 1, wherein the conductive adhesive has adhesiveness for limiting a displacement of the thermal interface material relative to the back side metallization.

11. The electronic package of claim 1, wherein the conductive adhesive is made of a composite material composed of a polymer adhesive and the metal fillers.
